(19) United States
(12) Patent Application Publication
(10) Pub. No.: US 2024/0274595 A1
(43) Pub. Date: Aug. 15, 2024

(54) INTEGRATED CIRCUIT WITH PROTECTIVE ELEMENT

(71) Applicant: Renesas Electronics America Inc., Milpitas, CA (US)

(72) Inventors: Edgardo LABER, San Jose, CA (US); James Edwin VINSON, Palm Bay, FL (US)

(73) Assignee: Renesas Electronics America Inc., Milpitas, CA (US)

(21) Appl. No.: 18/496,529

(22) Filed: Oct. 27, 2023

Related U.S. Application Data
(60) Provisional application No. 63/484,266, filed on Feb. 10, 2023.

(51) Int. Cl. H01L 27/02; H01L 23/522; H01L 23/525

(52) U.S. Cl. CPC H01L 27/0248; H01L 23/5228; H01L 23/5256; H01L 28/20

(57) ABSTRACT

An integrated circuit is presented. The integrated circuit includes an internal circuit; a contact pad; and a protective element coupled between the internal circuit and the contact pad. The protective element is operable in a first state or a second state. In the first state the protective element passes a current between the internal circuit and the contact pad. When the current is above a threshold value the protective element changes from the first state to the second state to reduce or prevent the current from flowing between the internal circuit and the contact pad. The protective element may be used to prevent damage to an external circuit connected to the integrated circuit.

### CROSS-REFERENCE TO RELATED APPLICATION

The present application claims the benefit of U.S. Patent Application No. 63/484,266, titled “HIGH CURRENT SILICIDED POLYSILICON RESISTORS FOR BATTERY MANAGEMENT SYSTEM PROTECTION” and filed on Feb. 10, 2023, which is hereby incorporated by reference in its entirety.

### TECHNICAL FIELD

The present disclosure relates to an integrated circuit with protective element. In particular, the disclosure relates to an integrated circuit for use with an external circuit, in which the protective element prevents damaging the external circuit.

### BACKGROUND

In typical battery management systems, the internal circuits of the integrated circuit IC chip are directly coupled to the external circuit components. If a fault occurs in the internal circuitry of the IC chip, then a high current may automatically surge through to the external circuit elements which can lead to damage of the external circuit. Therefore, a protective circuit is needed. Current solutions typically implement an external fuse to prevent the surge of high current, however this solution is slow and expensive.

It is an object of the disclosure to address one or more of the above-mentioned limitations.

### SUMMARY

According to a first aspect of the disclosure, there is provided an integrated circuit comprising an internal circuit; a contact pad; and a protective element coupled between the internal circuit and the contact pad, the protective element being operable in a first state or a second state; wherein in the first state the protective element is configured to pass a current between the internal circuit and the contact pad, and wherein when the current is above a threshold value the protective element is configured to change from the first state to the second state to prevent the current from flowing between the internal circuit and the contact pad.

Optionally, wherein in the first state the protective element has a low impedance to allow current flow.

Optionally, wherein in the second state the protective element has a high impedance to reduce or prevent current flow. For instance, the protective element may break open to prevent current flow. When the connection between the two terminals of the protective element is open, there is no current flow.

Optionally, the protective element is a fusible link.

Optionally, the protective element comprises a resistor configured to change its impedance upon temperature change.

Optionally, the resistor comprises a single layer having a single resistance. For instance, the protective element may be a wire such as a bond wire.

Optionally, wherein when the current is above the threshold value, the single layer liquifies, hence increasing the impedance of the resistor.

Optionally, the resistor comprises a first layer having a first resistance and a second layer having a second resistance, the first resistance being lower than the second resistance.

Optionally, when the current is above the threshold value, the first layer liquifies, hence increasing the impedance of the resistor.

Optionally, the resistor is a silicide polysilicon resistor in which the first layer is a silicide layer, and the second layer is a polysilicon layer.

Optionally, wherein the polysilicon layer is doped.

Optionally, wherein the resistor has a geometry which defines the impedance of the protective element in at least one of the first state and second state.

Optionally, the resistor extends between a first end and second end and has a plurality of contact points at the first and second end.

For instance, the resistor may have two end portions provided with one or more contact points. The two end portions may be connected by a single channel. The single channel may extend between two end regions. The end regions may have a different shapes, for instance they may have a tapered profile.

Optionally, wherein the protective element comprises a plurality of resistors.

Optionally, wherein the resistors among the plurality of resistors are coupled in series or in parallel.

Optionally, the integrated circuit comprises a connector connecting the contact pad to a package pin.

Optionally, wherein the connector is one of a bond-wire, a copper pillar or a solder ball.

According to a second aspect of the disclosure, there is provided a system comprising an integrated circuit according to the first aspect, coupled to an external circuit.

Optionally, the external circuit comprises a battery cell circuit and wherein the system forms a battery management system.

According to a third aspect of the disclosure, there is provided a method for protecting an external circuit coupled to an integrated circuit having an internal circuit and a contact pad, the method comprising:
providing the integrated circuit with a protective element coupled between the internal circuit and the contact pad, the protective element being operable in a first state or a second state;
wherein in the first state the protective element is configured to pass a current between the internal circuit and the contact pad, and wherein when the current is above a threshold value the protective element is configured to change from the first state to the second state to reduce or prevent the current from flowing between the internal circuit and the contact pad.

### DESCRIPTION OF DRAWINGS

The disclosure is described in further detail below by way of example and with reference to the accompanying drawings, in which:

FIG. 1 is an integrated circuit with protective element according to the present disclosure;

FIG. 2 is a diagram showing how the protective element may be arranged in the integrated circuit of FIG. 1;

FIG. 3 is a cross sectional view of an example embodiment of a protective element for use in the circuits of FIGS. 1 and 2;

FIG. 4A is a top view of a first geometry of the protective element of FIG. 3;

FIG. 4B is a top view of a second geometry of the protective element of FIG. 3;

FIG. 4C is a top view of a third geometry of the protective element of FIG. 3;

FIG. 5 is a system comprising the integrated circuit of FIG. 1 coupled to an external circuit;

FIG. 6 is a diagram of power management system; and

FIG. 7 is a flow-chart of a method for protecting an external circuit coupled to an integrated circuit.

### DETAILED DESCRIPTION

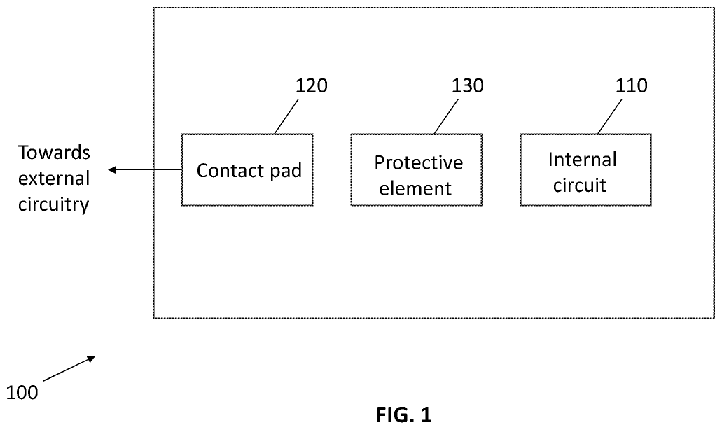

FIG. 1 is a diagram of an integrated circuit 100 according to the present disclosure. The integrated circuit 100 comprises an internal circuit 110 and a contact pad 120. The contact pad 120 could be, for example, a passivation opening or bond-pad. The integrated circuit 100 further comprises a protective element 130 which is coupled between the internal circuit 110 and the contact pad 120.

The protective element 130 is operable in two states: a first state also referred to as normal state and a second state, also referred to as protective state. When a current flows within the integrated circuit 100 via the contact pad 120, the protective element 130 operates in the first state. During this normal state, the element 130 operates with a low impedance to allow the current to flow between the internal circuit 110 and the contact pad 120. If the current passing through the protective element 130 surpasses a threshold level, then the protective element 130 changes from the first state to the second state. In the protective state, the protective element 130 opens or operates with a high impedance to prevent the current from flowing between the internal circuit 110 and the contact pad 120.

In case of a fault occurring in the internal circuit 110, a high current may be generated and flow between the internal circuits and the contact pad 120. The protective element 130 is designed to reduce or prevent a current above a threshold value to be delivered to the external circuitry via the contact pad 120. The threshold level or threshold current is determined by the properties of the protective element 130.

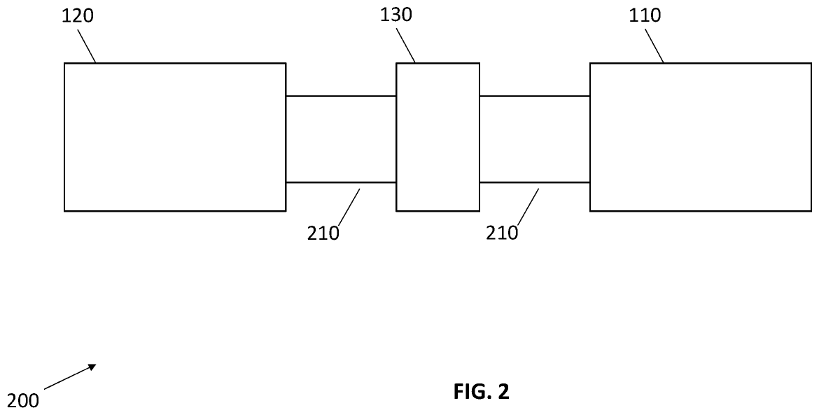

FIG. 2 shows an example of how the protective element 130 can be coupled between the internal circuit 110 and the contact pad 120. The protective element 130 is connected between the internal circuit 110 and the contact pad 120 by means of metal connections 210. The protective element 130 could be, for example, a fusible link.

The protective element 130 may be implemented as a resistor such as a single conductive layer resistor. For instance, the resistor may be a wire, also referred to as bond wire, made of a metallic or metal alloy material.

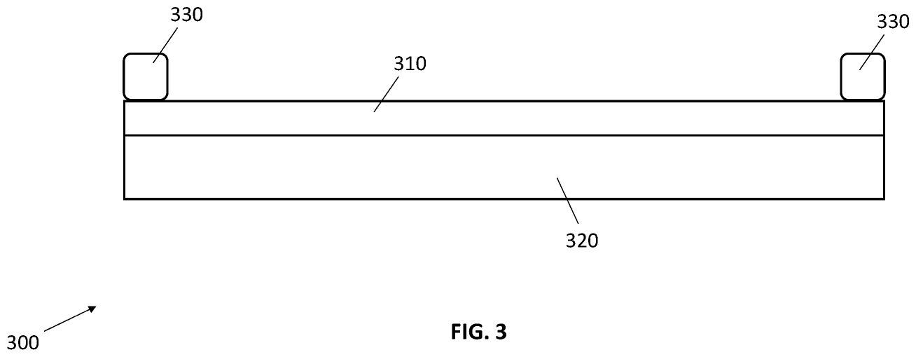

FIG. 3 shows an example embodiment of a cross sectional view of the protective element 130. In this figure, the protective element 130 is a fusible link in the form of a resistor 300 which is configured to change its impedance upon a change in temperature. In this example, the resistor 300 includes a first layer 310 having a first resistance and a second layer 320 having a second resistance. The first resistance is lower than the second resistance. The resistor 300 extends between a first end and a second end. A plurality of contact points 330 are provided at each end on the first layer 310.

The first layer 310 is the main conductive layer of the resistor 300, such that when the resistor 300 is in the first (normal) state, a current can flow easily due to its lower impedance. When a current equal or above a threshold value flows through the resistor 300, the first layer 310 is heated and begins to liquefy. The melting of the first layer 310 causes it to begin to shift across the second layer 320. As the temperature increases, a separation starts to form between the first layer and the second layer, hence increasing the impedance of the resistor 300. This prevents the current from flowing and the resistor 300 is operating in the second state (protective state). The plurality of contact points 330 allow for the resistor 300 to be implemented within the integrated circuit 100.

The first layer 310 of the resistor 300 could be, for example, a layer of silicide and the second layer 320 could be, for example, a layer of polysilicon, hence forming a silicided polysilicon resistor. The silicide layer is formed by depositing polysilicon on to a dielectric which is then covered with metal. When the metal is heated, it reacts with the polysilicon and this process forms the silicide layer. Once the silicide has been formed, it is patterned into the desired geometry.

The silicide is a low-resistance, conductive layer which allows current to flow through the resistor 300 with a low impedance. The silicide layer 310 can achieve a much lower resistance than can be done through polysilicon or doped polysilicon alone. When a current higher than the threshold value flows through the resistor 300, the silicide is heated and begins to shift across the polysilicon. As the silicide migrates, a separation starts to form between the silicide and the polysilicon increasing the impedance of the resistor 300. A factor that is considered in patterning the silicide is the current density desired for the silicide layer 310. The current density capability needs to be high enough, such that the silicide does not liquify during normal state operation. However, the current density capability also needs to be low enough such that an excessive heat build-up occurs at currents higher than the threshold value such that the silicide melts and migrates quickly and effectively. The polysilicon layer 320 can be doped or left intrinsic. In each case the silicide is the main conductive layer.

The threshold value of current that the protective element 130 changes operational state at can be modified by implementing the protective element 130 as a fusible link with a plurality of resistors coupled in series or in parallel.

When the protective element 130 is implemented as a resistor 300 another way to adapt the threshold value is through the physical geometry of the first (silicide) layer 310 and the second (polysilicon) layer 320.

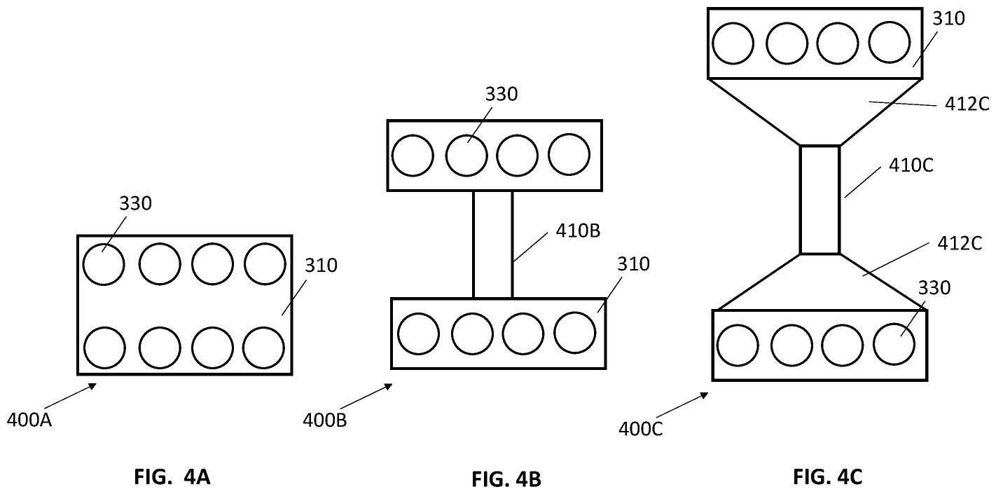

FIGS. 4A, 4B and 4C show three example geometries that the resistor 300 can take. It will be appreciated that other geometries may also be considered . The geometry affects a number of factors of the resistor which define the maximum value of DC current for normal operation state of the protective element 130. In particular, the different geometries react to heat or conduct heat differently. Therefore, some geometries lead to the resistor melting and separating more easily than other geometries. The resistor may have a neck feature joining both ends of the resistor. The size of the neck also defines the current capability to fuse open within a specified time duration: in other words how much current is required to melt the resistor 300.

The resistor may have two end portions provided with one or more contact points. The two end portions may be connected by a single channel. The single channel may extend between two end regions. The end regions may have a different shapes, for instance they may have a tapered profile.

FIGS. 4A, 4B and 4C show a top view of a bar 400A geometry, a straight geometry 400B and a taper 400C geometry, respectively. The bar 400A geometry shows the first (silicide) layer 310 with a plurality of contact points 330. This structure has a lower resistance compared to the straight 400B or taper 400C geometries. Two sets of contacts are provided, one at each end. The straight 400B geometry shows two silicide layers 310 with a plurality of contact points 330 separated by a single bar of silicided polysilicon 410B, connected between the centers of the longer edge of the first layer 310. The taper 400C geometry is similar to the straight 400B geometry, except the bar of silicided polysilicon 410C has tapered material 412C attached to its ends such that the bar 410C is connected across the entire long edge of the side of the first layer 310. The number of contact points 330 and the spacing between them affects the resistance and current capabilities of the different geometries. FIGS. 4B and 4C may be example embodiments of the protective element shown in FIG. 3.

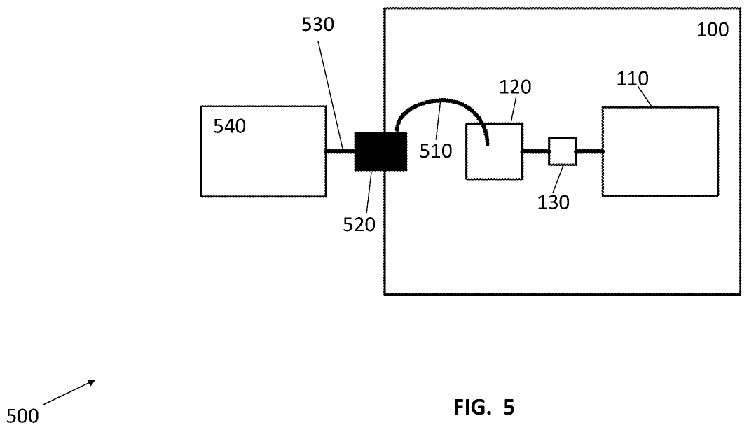

FIG. 5 is a system comprising the integrated circuit of FIG. 1 coupled to an external circuit. the same reference numerals have been used to describe the integrated circuit of FIG. 1.

The system 500 shows an external circuit 540 coupled to the internal circuit 120 of the integrated circuit 100. The external circuit 540 and internal circuit 120 are coupled via the protection element 130, contact pad 120, a connector 510 and a package pin 520. The connector 510 could be implemented in different ways, for example, as a bond-wire, one or more copper pillars, or solder balls, among others. The package pin 520 forms a link between the internal circuits and the external circuits via a printed circuit board (PCB) metal trace 530.

As explained above, the protective element 130 has an adaptive impedance. The impedance of the protective element 130 changes in response to the current flowing through it. The protective element 130 can be integrated into a wafer processing flow during the manufacture of the integrated circuit 100. In normal circuit operation, the protective element 130 operates in the first state with a low impedance and does not have a significant impact on the way the current flows between the internal and external circuits.

When a fault condition occurs in the internal circuit 110, the current flowing through the internal circuit may exceed the threshold value. The protective element 130 then changes to the second state and it opens or operates with a higher impedance level. The increase in impedance of the protective element 130 will prevent the high current from flowing into the external circuit 540, hence protecting any electronic components in the external circuit from being damaged. There are several reasons why a fault condition may occur. These include: misuse of the internal circuit by connecting components that should not be connected together, degradation over time of the integrated circuit and defects in the integrated circuit.

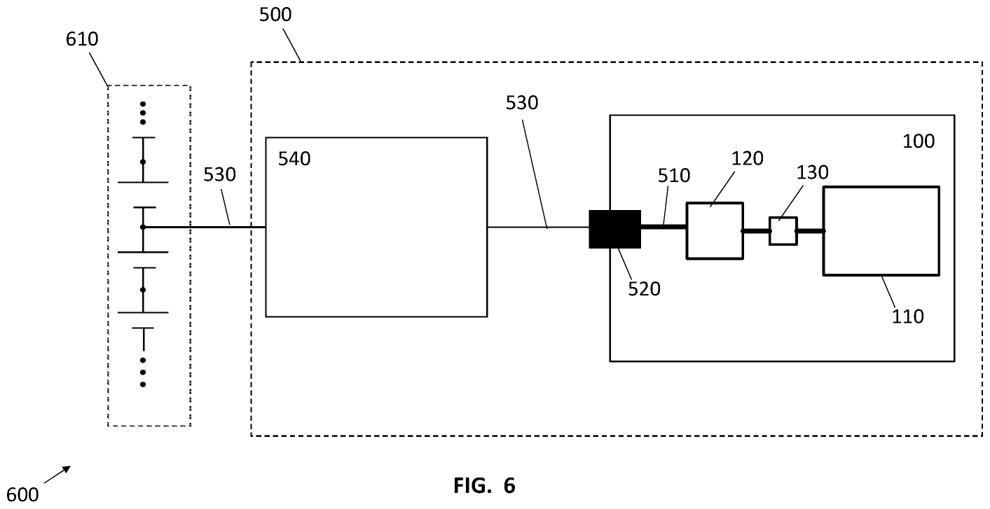

FIG. 6 is a diagram of a power management system 600 comprising a series of battery cells 610 coupled to the system 500 from FIG. 5 via a wire 530. The system 600 could be, for example, a battery management system. The external circuit 540 can be used for a variety of functions. The external circuit can be used to reduce or filter any fast changes in voltage, it can amplify the balancing capability or set the level of balancing currents for the system 600. It can also be used to control the turning on and off of the devices used for cell balancing functions. These functions are just some examples and not an exhaustive list.

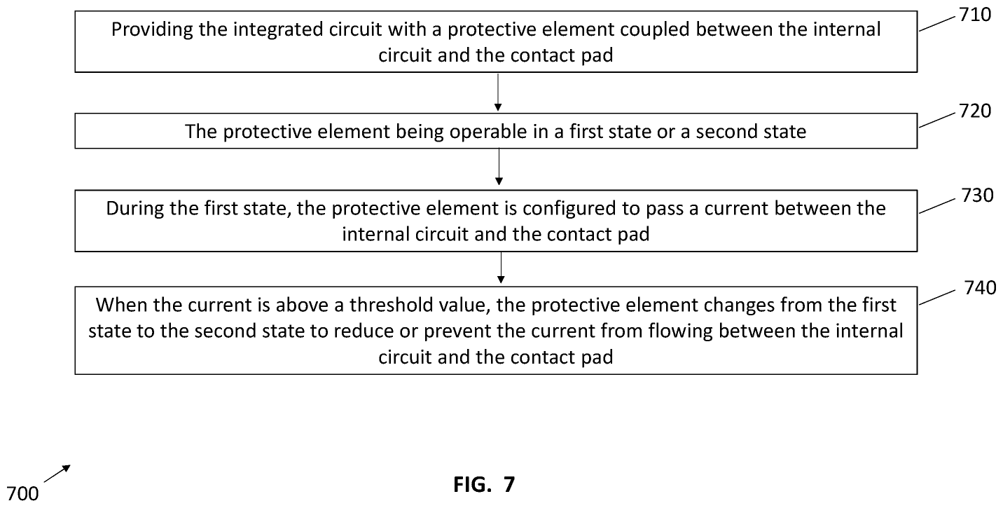

FIG. 7 is a flow-chart of a method for protecting an external circuit coupled to an integrated circuit having an internal circuit and a contact pad.

At step 710 the integrated circuit is provided with a protective element coupled between the internal circuit and the contact pad. The contact pad could be, for example, a passivation opening or bond-pad. The protective element is operable in a first state or a second state according to step 720. The protective element could be, for example, a fusible link, a resistor or a silicide polysilicon resistor.

At step 730, the protective element is operating in the first state and is configured to pass a current between the internal circuit and the contact pad. When the current is above a threshold value, the protective element changes operation from the first state to the second state as shown at step 740.

During the second state of operation the protective element is configured to reduce or prevent the current from flowing between the internal circuit and the contact pad.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

What is claimed is:

1. An integrated circuit comprising:
an internal circuit;
a contact pad; and
a protective element coupled between the internal circuit and the contact pad, the protective element being operable in a first state or a second state;
wherein in the first state the protective element is configured to pass a current between the internal circuit and the contact pad, and wherein when the current is above a threshold value the protective element is configured to change from the first state to the second state to reduce or prevent the current from flowing between the internal circuit and the contact pad.

2. The integrated circuit as claimed in claim 1, wherein in the first state the protective element has a low impedance to allow current flow.

3. The integrated circuit as claimed in claim 2, wherein in the second state the protective element has a high impedance to reduce or prevent current flow.

4. The integrated circuit as claimed in claim 2, wherein the protective element is a fusible link.

5. The integrated circuit as claimed in claim 1, wherein the protective element comprises a resistor configured to change its impedance upon temperature change.

6. The integrated circuit as claimed in claim 5, wherein the resistor comprises a single layer having a single resistance.

7. The integrated circuit as claimed in claim 6, wherein when the current is above the threshold value, the single layer liquifies, hence increasing the impedance of the resistor.

8. The integrated circuit as claimed in claim 5, wherein the resistor comprises a first layer having a first resistance and a second layer having a second resistance, the first resistance being lower than the second resistance.

9. The integrated circuit as claimed in claim 8, wherein when the current is above the threshold value, the first layer liquifies, hence increasing the impedance of the resistor.

10. The integrated circuit as claimed in claim 9, wherein the resistor is a silicide polysilicon resistor in which the first layer is a silicide layer, and the second layer is a polysilicon layer.

11. The integrated circuit as claimed in claim 10, wherein the polysilicon layer is doped.

12. The integrated circuit as claimed in claim 5, wherein the resistor has a geometry which defines the impedance of the protective element in at least one of the first state and second state.

13. The integrated circuit as claimed in claim 12, wherein the resistor extends between a first end and second end and has a plurality of contact points at the first and second end.

14. The integrated circuit as claimed in claim 1, wherein the protective element comprises a plurality of resistors.

15. The integrated circuit as claimed in claim 14, wherein the resistors among the plurality of resistors are coupled in series or in parallel.

16. The integrated circuit as claimed in claim 1, comprising a connector connecting the contact pad to a package pin.

17. The integrated circuit as claimed in claim 16, wherein the connector is one of a bond-wire, a copper pillar or a solder ball.

18. A system comprising an integrated circuit as claimed in claim 1, coupled to an external circuit.

19. The system as claimed in claim 18, wherein the external circuit comprises a battery cell circuit and wherein the system forms a battery management system.

20. A method for protecting an external circuit coupled to an integrated circuit having an internal circuit and a contact pad, the method comprising:
providing the integrated circuit with a protective element coupled between the internal circuit and the contact pad, the protective element being operable in a first state or a second state;
wherein in the first state the protective element is configured to pass a current between the internal circuit and the contact pad, and wherein when the current is above a threshold value the protective element is configured to change from the first state to the second state to reduce or prevent the current from flowing between the internal circuit and the contact pad.
